(19) United States
(12) Patent Application Publication
(10) Pub. No.: US 2026/0305546 A1
(43) Pub. Date: Oct. 8, 2026

(54) SYSTEM AND METHOD FOR DETERMINING ALIGNMENT FAULTED MOBILE IRRIGATION TOWER

(71) Applicant: Lindsay Corporation, Omaha, NE (US)

(72) Inventors: Luke Barker, Omaha, NE (US); Mark William Miller, Omaha, NE (US); Derick Frauendorfer, Omaha, NE (US); Brian Klawinski, Omaha, NE (US)

(21) Appl. No.: 19/172,853

(22) Filed: Apr. 8, 2025

(51) Int. Cl. A01G 25/16; A01G 25/09; G01R 31/08; G01R 31/327

(52) U.S. Cl. CPC A01G 25/16; A01G 25/09; G01R 31/08; G01R 31/3274; G01R 31/3275

(57) ABSTRACT

A control system for a mobile irrigation system having a plurality of mobile towers supporting a plurality of spans. The control system comprises a number of safety switches, a number of transceivers, and a central controller. Each safety switch is positioned on or near one of the mobile towers and configured to change from a closed position to an open position. Each transceiver is positioned on or near one of the mobile towers and is configured to transmit an identification signal to the central controller upon a corresponding one of the safety switches being in the open position such that the safety switch in the open position is identified based on the identification signal.

### BACKGROUND

Mobile irrigation systems comprise a plurality of spaced-apart, motorized, and self-propelled towers which support a fluid-carrying conduit and sprayer system that sprays the fluid on one or more crops. In a center-pivot irrigation system, the conduit is coupled to a fluid source at a center pivot point, and the towers travel in a roughly circular path around the center pivot. Between each adjacent pair of towers is a plurality of conduit sections, wherein each adjacent pair of conduit sections is coupled with a flexible joint. The towers travel independently of one another and may travel at different speeds and at different times. Thus, during normal operation, the towers may travel such that there is a non-zero alignment angle between adjacent sections of the conduit. Some variation of the alignment angle, both positive and negative, is acceptable. However, for numerous reasons the alignment angle may exceed a safe threshold. To monitor the alignment angle, each tower includes a safety switch coupled to the conduit on each adjacent section. The safety switch will open if the alignment angle between the two associated sections of conduit exceeds the safe threshold. A central controller, which controls operation of the irrigation system, senses the open switch and shuts down the operation of the irrigation system. The central controller may also transmit an error message which alerts a technician to investigate the irrigation system and repair, replace, or reposition the misaligned tower. Unfortunately, it may be difficult to determine which tower is misaligned without visually inspecting each tower. This can be quite tedious and time consuming.

### SUMMARY

Embodiments of the present invention address one or more of the above-mentioned problems and related problems by providing mobile irrigation systems and corresponding control systems that identify misaligned towers. The control systems include safety switches paired with transceivers from which identifying signals are transmitted back to central controllers. In this way, misaligned towers are identified without the need for visual inspection. The control systems do not require complex after-market installations and can be easily incorporated into conventional mobile irrigation systems.

An embodiment of the invention is a control system for a mobile irrigation system having a number of mobile towers supporting a number of spans. The control system broadly comprises a number of safety switches, a number of transceivers, and a central controller. Each safety switch is positioned on or near one of the mobile towers and is configured to change from a closed position to an open position. Each transceiver is positioned on or near one of the mobile towers and is configured to transmit an identification signal to the central controller upon a corresponding safety switch being in the open position such that the safety switch in the open position is identified based on the identification signal.

Another embodiment is a control system for a mobile irrigation system having a number of mobile towers supporting a number of spans. The control system broadly comprises a number of safety switches, a number of passive RFID transceivers, and a central controller including an active radio frequency identification device (RFID) transceiver. Each safety switch is positioned on or near one of the mobile towers and is configured to change from a closed position to an open position. Each passive RFID transceiver is positioned on or near one of the mobile towers and is configured to transmit an identification signal to the central controller upon a corresponding safety switch being in the open position and an excitation signal being transmitted to the passive RFID transceiver such that the safety switch in the open position is identified based on the identification signal.

Yet another embodiment is a control system for a mobile irrigation system having a number of mobile towers supporting a number of spans. The control system broadly comprises a number of safety switches, a number of active RFID transceivers, and a central controller. Each safety switch is positioned on or near one of the mobile towers and is configured to change from a closed position to an open position. Each active RFID transceiver is positioned on or near one of the mobile towers and is configured to transmit an identification signal to the central controller upon a corresponding safety switch being in the open position such that the safety switch in the open position is identified based on the identification signal.

This summary is provided to introduce a selection of concepts in a simplified form that are further described below in the detailed description. This summary is not intended to identify key features or essential features of the claimed subject matter, nor is it intended to be used to limit the scope of the claimed subject matter. Other aspects and advantages of the current invention will be apparent from the following detailed description of the embodiments and the accompanying drawing figures.

### BRIEF DESCRIPTION OF DRAWINGS

Embodiments of the current invention are described in detail below with reference to the attached drawing figures, wherein:

FIG. 1 is a perspective view of a mobile irrigation system constructed in accordance with an embodiment of the invention;

FIG. 2 is a schematic diagram of a control system of the mobile irrigation system of FIG. 1 constructed in accordance with an embodiment of the invention;

FIG. 3 is a flow diagram of certain method steps of controlling the irrigation system of FIG. 1 in accordance with an embodiment of the invention;

FIG. 4 is a flow diagram of certain method steps of controlling the irrigation system of FIG. 1 in accordance with another embodiment of the invention;

FIG. 5 is a schematic diagram of a control system constructed in accordance with another embodiment of the invention;

FIG. 6 is a flow diagram of certain method steps of controlling an irrigation system in accordance with another embodiment of the invention;

FIG. 7 is a schematic diagram of a control system constructed in accordance with another embodiment of the invention;

FIG. 8 is a flow diagram of certain method steps of controlling an irrigation system in accordance with another embodiment of the invention;

FIG. 9 is schematic diagram of a control system constructed in accordance with another embodiment of the invention; and

FIG. 10 is a flow diagram of certain method steps of controlling an irrigation system in accordance with another embodiment of the invention.

The drawing figures do not limit the current invention to the specific embodiments disclosed and described herein. The drawings are not necessarily to scale, emphasis instead being placed upon clearly illustrating the principles of the invention.

### DETAILED DESCRIPTION OF THE INVENTION

The following detailed description of the technology references the accompanying drawings that illustrate specific embodiments in which the technology can be practiced. The embodiments are intended to describe aspects of the technology in sufficient detail to enable those skilled in the art to practice the technology. Other embodiments can be utilized and changes can be made without departing from the scope of the current invention. The following detailed description is, therefore, not to be taken in a limiting sense. The scope of the current invention is defined only by the appended claims, along with the full scope of equivalents to which such claims are entitled.

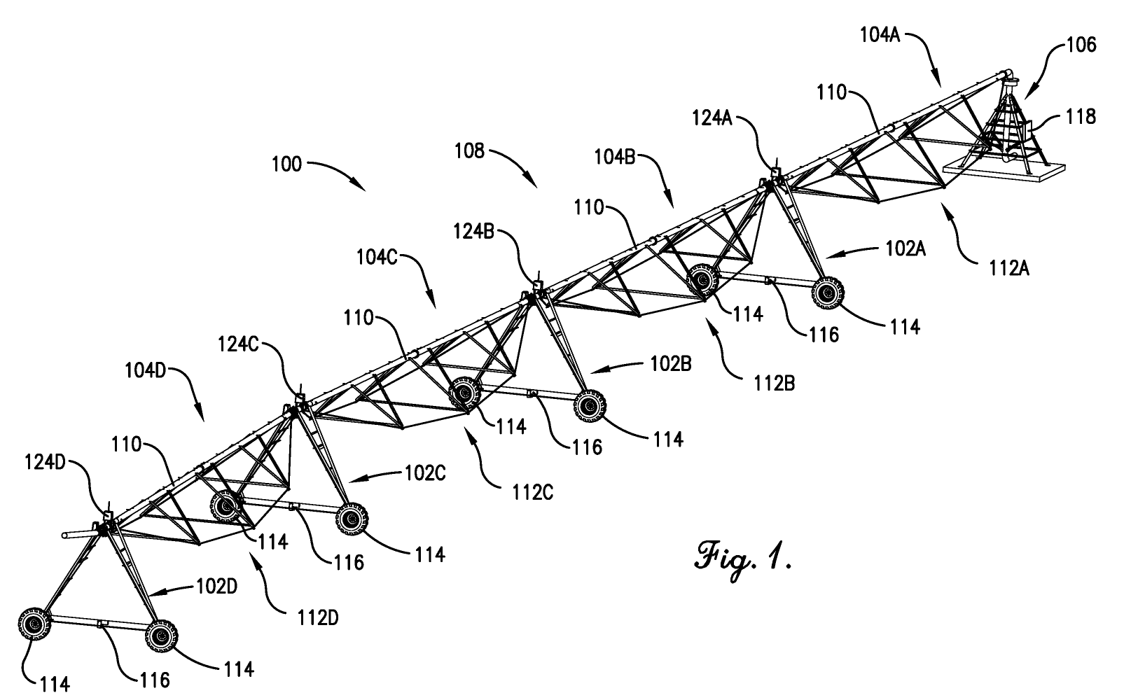

A mobile irrigation system 100 constructed in accordance with various embodiments of the current invention is shown in FIG. 1. The irrigation system 100 broadly comprises a plurality of towers 102A-D which support fluid delivery components along with a control system 104 that controls operation of the irrigation system 100. An exemplary embodiment of the irrigation system 100, shown in FIG. 1, is a center pivot irrigation system and broadly comprises a fixed center pivot 106 and a main section 108 pivotally connected to the center pivot 106. The irrigation system 100 may also comprise an extension arm (also commonly referred to as a “swing arm” or “corner arm”) pivotally connected to the free end of the main section 108. The irrigation system 100 may also be embodied by a lateral, or linear, move apparatus which irrigates while moving in a linear, or near-linear, direction without departing from the scope of the current invention.

The fixed center pivot 106 may be a tower or any other support structure about which the main section 108 may pivot. The center pivot 106 has access to a well, water tank, or other source of water or other fluid and may also be coupled with a tank or other source of agricultural products to inject fertilizers, pesticides and/or other chemicals into the water for application during irrigation. The center pivot 106 may supply water to a conduit 110 which carries the water along the length of the main section 108.

The main section 108 may comprise any number of mobile support towers 102A-D, the outermost tower 102D of which is referred to herein as an end tower. The towers 102A-D are connected to the fixed center pivot 106 and to one another by truss sections 112A-D or other supports to form a number of interconnected spans.

The towers 102A-D may have wheels 114, at least one of which is driven by suitable drive motors 116. Each motor 116 turns at least one of its wheels 114 through a drive shaft to propel its tower 102 and thus the main section 108 in a circle about the center pivot 106 to irrigate a field. The motors 116 may also have several speeds or be equipped with variable speed drives. The operation of the motors 116, such as whether they are on or off, the speed of travel, and the direction of travel, may be controlled with one or more electronic signals or digital data.

Each of the truss sections 112A-D carries or otherwise supports the conduit 110 and other fluid distribution mechanisms that are connected in fluid communication to the conduit 110. Fluid distribution mechanisms may include sprayers or diffusers, each optionally attached to a drop hose, or the like. Between each adjacent pair of towers 102A-D is a successive one of a plurality of sections of the conduit 110, wherein each adjacent pair of conduit 110 sections is coupled with a successive one of a plurality of joints that is flexible. In addition, the conduit 110 may include one or more valves which control the flow of water through the conduit 110. The opening and closing of the valves may be automatically controlled with an electronic signal or digital data.

The irrigation system 100 may also include wired or wireless communication electronic components that communicate with a communication network and allow the valves and the motors 116 to receive the electronic signals and/or digital data which control the operation of the valves and the motors 116.

The irrigation system 100 may also include an optional extension arm (not shown) pivotally connected to the end tower 102D and may be supported by a swing tower with steerable wheels driven by a motor. The extension arm may be joined to the end tower 102D by an articulating pivot joint. The extension arm is folded in relative to the end tower 102D when it is not irrigating a corner of a field and may be pivoted outwardly away from the end tower 102D while irrigating the corners of a field.

The irrigation system 100 illustrated in FIG. 1 has four towers 102A-D; however, it may comprise any number of towers, truss sections, wheels, and drive motors without departing from the scope of the current invention.

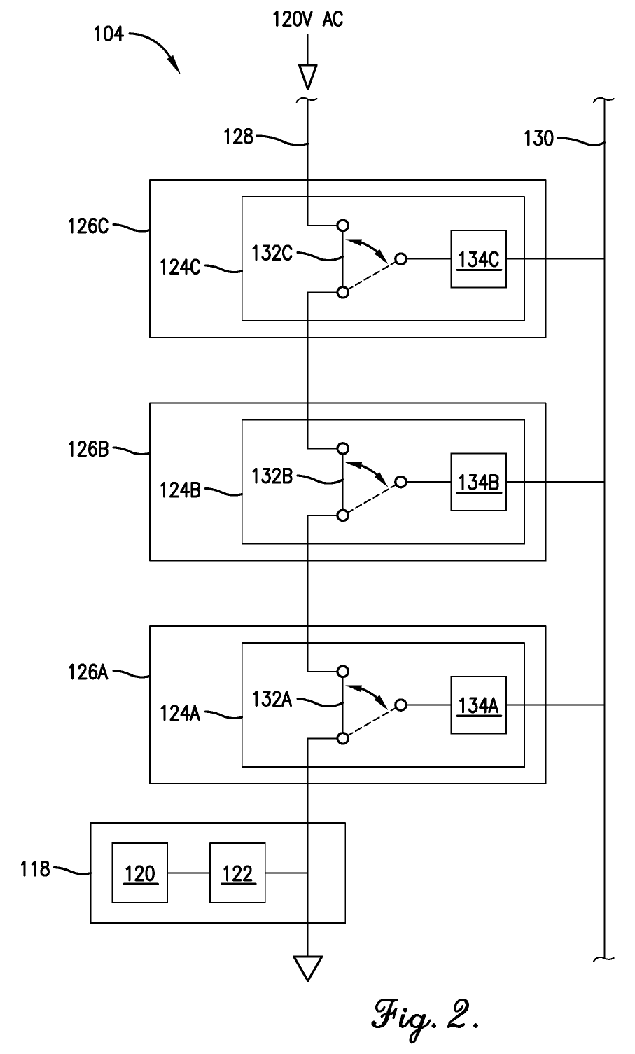

Turning to FIG. 2, the control system 104 controls the irrigation system 100, intakes commands and data from an operator or other source, and outputs statuses, data, alerts, and notifications relating to operation of the irrigation system 100. The control system 104 may also detect an alignment fault and determine which tower has the identified alignment fault. To that end, the control system 104 may include a central control panel 118 having a central controller 120 and a transceiver 122, and a plurality of tower control panels 124A-C each having a respective tower controller 126A-C. The control system 104 may further include a safety cable 128, a common cable 130, a plurality of safety switches 132A-C, and a plurality of frequency generators 134A-C.

The central control panel 118 and hence the central controller 120 may be positioned on or near the fixed center pivot 106 and may be communicatively connected to the tower controllers 124A-C. The central controller 120 may comprise one or more processors that include electronic hardware components such as microprocessors (single-core or multi-core), microcontrollers, digital signal processors (DSPs), field-programmable gate arrays (FPGAs), analog and/or digital application-specific integrated circuits (ASICs), intelligence circuitry, or the like, or combinations thereof. The central controller 120 may generally execute, process, or run instructions, code, code segments, code statements, software, firmware, programs, applications, apps, processes, services, daemons, or the like. The central controller 120 may also include hardware components such as registers, finite-state machines, sequential and combinational logic, configurable logic blocks, and other electronic circuits that can perform the functions necessary for the operation of the current invention. In certain embodiments, the central controller 120 may include multiple computational components and functional blocks that are packaged separately but function as a single unit. In some embodiments, the central controller 120 may further include multiprocessor architectures, parallel processor architectures, processor clusters, and the like, which provide high performance computing. The central controller 120 may be in electronic communication with the tower controllers 124A-C and other electronic components through serial or parallel links that include universal busses, address busses, data busses, control lines, and the like. In addition, the central controller 120 may include analog to digital converters (ADCs) to convert analog electronic signals to (streams of) digital data values and/or digital to analog converters (DACs) to convert (streams of) digital data values to analog electronic signals.

The central controller 120 may also include a user interface having a display and a number of user inputs. The display may be a touchscreen, an LCD screen, or the like. The user inputs may be physical controls (e.g., buttons, dials, knobs, sliders, a mouse, a joystick, or the like) or may be virtual controls presented by the touchscreen.

The central controller 120 may be operable, configured, and/or programmed to perform the functions, operations, processes, methods, and/or algorithms by utilizing hardware, software, firmware, or combinations thereof. The central controller 120 may also have access to, and be in electronic communication with, cloud computing services, wherein a portion of the functions, operations, processes, methods, and/or algorithms of the central controller 120 are performed by computing resources off-site. Additionally, or alternatively, the central controller 120 may include components, such as cloud computing components, that are physically located in a plurality of different geolocations. The components are able to communicate with each other to provide cohesive operation.

Each of the tower controllers 124A-C may be positioned on or near one of the towers 102A-C and may be communicatively connected to the other tower controllers 124A-C and the central controller 120. The tower controllers 124A-C may be substantially similar and thus only tower controller 124A will be described in detail. Much like the central controller 120, the tower controller 124A may comprise one or more processors that include electronic hardware components such as microprocessors (single-core or multi-core), microcontrollers, digital signal processors (DSPs), field-programmable gate arrays (FPGAs), analog and/or digital application-specific integrated circuits (ASICs), intelligence circuitry, or the like, or combinations thereof. The tower controller 124A may generally execute, process, or run instructions, code, code segments, code statements, software, firmware, programs, applications, apps, processes, services, daemons, or the like. The tower controller 124A may also include hardware components such as registers, finite-state machines, sequential and combinational logic, configurable logic blocks, and other electronic circuits that can perform the functions necessary for the operation of the current invention. In certain embodiments, the tower controller 124A may include multiple computational components and functional blocks that are packaged separately but function as a single unit. In some embodiments, the tower controller 124A may further include multiprocessor architectures, parallel processor architectures, processor clusters, and the like, which provide high performance computing. The tower controller 124A may be in electronic communication with the other tower controllers 124A-C, the central controller 120, and other electronic components through serial or parallel links that include universal busses, address busses, data busses, control lines, and the like. In addition, the tower controller 124A may include analog to digital converters (ADCs) to convert analog electronic signals to (streams of) digital data values and/or digital to analog converters (DACs) to convert (streams of) digital data values to analog electronic signals.

The tower controller 124A may be operable, configured, and/or programmed to perform the functions, operations, processes, methods, and/or algorithms by utilizing hardware, software, firmware, or combinations thereof. The tower controller 124A may also have access to, and be in electronic communication with, cloud computing services, wherein a portion of the functions, operations, processes, methods, and/or algorithms of the tower controller 124A are performed by computing resources off-site. Additionally, or alternatively, the tower controller 124A may include components, such as cloud computing components, that are physically located in a plurality of different geolocations. The components are able to communicate with each other to provide cohesive operation.

The safety cable 128 may extend from the central pivot 106 to the end tower 124D and may provide power to and be communicatively connected to the central controller 120 and the tower controllers 124A-C. The safety cable 128 may be an irrigation cable as defined in the National Electric Code (NFPA 70) edition 2020 (incorporated herein by reference in its entirety) in section 675.4. The safety cable 128 may include discrete insulated conductors, an inner jacket, a metallic covering, an outer jacket, and the like. The safety cable 128 may distribute electrical power and command signals to the tower controllers 124A-C. The safety cable 128 may carry 120VAC power or the like.

The common cable 130 may extend from the end tower 124D to the central pivot 106 and may act as a neutral cable path for certain communication signals as discussed below. Much like the safety cable 128, the common cable 130 may be an irrigation cable as defined previously. The common cable 130 may include discrete insulated conductors, an inner jacket, a metallic covering, an outer jacket, and the like. The common cable 130 may complete a signal circuit with the safety cable 128, one of the safety switches 132A-C, and a corresponding one of the frequency generators 134A-C as discussed below.

The safety switches 132A-C may be substantially similar so only safety switch 132A will be described in detail. The safety switch 132A may be electrically connected to the safety cable 128 via a normally closed pole to form a normally closed circuit along with the other safety switches. The safety switch 132A may be configured to open via a normally open pole, typically upon the corresponding span becoming misaligned. In the open state, the safety switch 132A may form a circuit with the safety cable 128, the frequency generator 134A, and the common cable 130.

The frequency generators 134A-C (i.e., oscillators) may be substantially similar and thus only frequency generator 134A will be described in detail. The frequency generator 134A may be positioned on or near tower 124A and wired between the normally open pole of the safety switch 132A and the common cable 130. The frequency generator 134A may be configured to emit a unique frequency (relative to the other frequency generators) when energized. More specifically, the frequency generator 134A may be configured to transmit a signal of the unique frequency back to the central controller 120. The frequency generator 134A may be powered by a low voltage DC signal such as 12VDC or 24VDC so that it is not hazardous to any maintenance personnel troubleshooting the irrigation system 100.

The frequency generator 134A may be pre-programmed to a specific or unique frequency for a specific tower number. For example, tower 124A may be allotted frequency A, tower 124B may be allotted frequency B, and so on. The frequency generator 134A may also be programmed and even reconfigured via dip switch settings. For example, an installer may pick a tower for installing frequency generator 134A, which would emit a frequency associated with a selected switch combination.

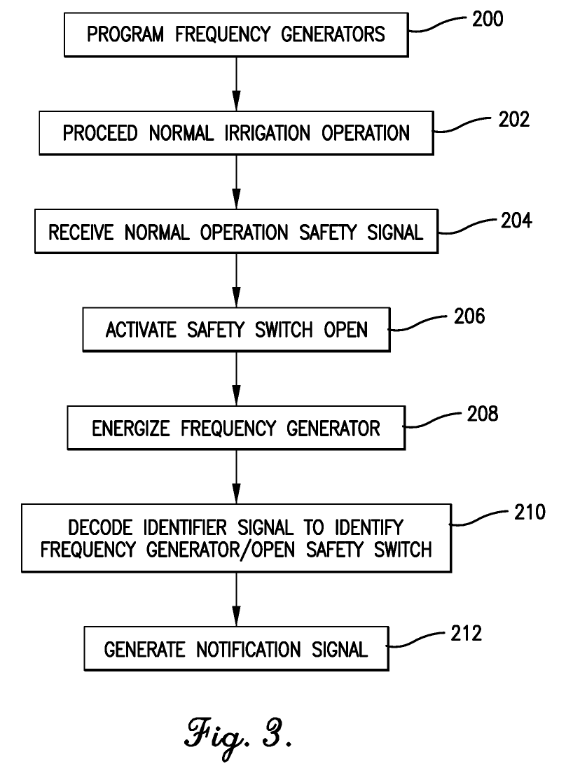

Turning to FIG. 3, use of the irrigation system 100 for detecting an alignment fault and identifying which tower has the alignment fault will now be described in more detail. First, the frequency generators 134A-C may be pre-programmed so that each frequency generator 134A-C has a frequency corresponding to a specific tower 124A-C, as shown in block 200. Alternatively, the frequency generators 134A-C could be programmed via dip switch settings such that an installer may select a frequency after installation on a given tower.

The mobile irrigation system 100 may then traverse a field for irrigation, application of agricultural products, or the like, as shown in block 202. The safety switches 132A-C may all be un-activated during normal aligned operation of the irrigation system 100 such that the central controller 120 receives a safety signal (e.g., a 120VAC signal), as shown in block 204.

One of the safety switches 132A-C may then be activated open upon a tower a corresponding span becoming misaligned, as shown in block 206. This activation represents an alignment fault and blocks the safety signal from reaching the central controller 120. The central controller 120 may detect the loss of the safety signal indicating an alignment fault.

The central controller 120 may then energize the frequency generator 134A-C corresponding to the activated safety switch 132A-C such that the energized frequency generator transmits a specific or unique identification signal to the central controller 120, as shown in block 208. The identification signal may be transmitted to the central controller 120 via the safety cable 128, the common cable 130, a separate circuit, or even wirelessly. The central controller 120 may then decode the identification signal and identify the frequency generator and/or tower associated with the frequency of the identification signal, as shown in block 210. The central controller 120 may then generate and transmit a notification signal representing a notification of the existence of an alignment fault and identification of the tower having the alignment fault, as shown in block 212. The notification signal may then be used to troubleshoot the irrigation system 100. That is, an inspector may go straight to the alignment faulted tower instead of having to search the entire irrigation system 100.

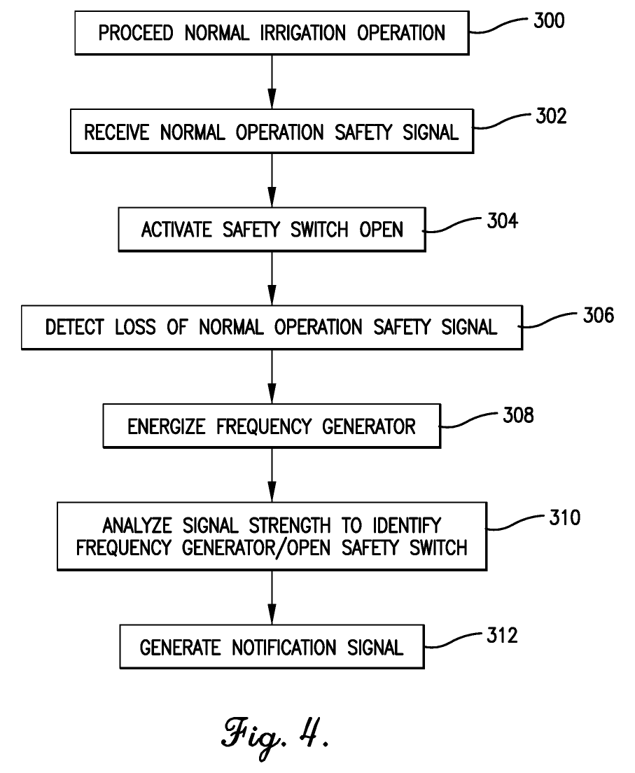

Turning to FIG. 4, an alternative method for utilizing the above frequency generators 134A-C or frequency generators that all emit equivalent frequencies will now be described. First, the mobile irrigation system 100 may traverse a field for irrigation, application of agricultural products, or the like, as shown in block 300. The safety switches 132A-C may all be un-activated during normal aligned operation of the irrigation system 100 such that the central controller 120 receives a safety signal (e.g., a 120VAC signal), as shown in block 302.

One of the safety switches 132A-C may then be activated upon a tower a corresponding span becoming misaligned, as shown in block 304. This activation represents an alignment fault and blocks the safety signal from reaching the central controller 120.

The central controller 120 may then detect the loss of the safety signal indicating an alignment fault, as shown in block 306. The central controller 120 may then energize the frequency generator 134A-C corresponding to the activated safety switch 132A-C such that the energized frequency generator transmits a generic or common frequency signal with a known power level or intensity (i.e., signal strength) to the central controller 120, as shown in block 308. The signal may be transmitted to the central controller 120 via the safety cable 128, the common cable 130, a separate circuit, or even wirelessly. The central controller 120 may then calculate or infer a distance to the energized frequency generator or tower according to a loss of signal strength at the transceiver 122 and identify the frequency generator and/or tower associated with the distance, as shown in block 310. The central controller 120 may then generate and transmit a notification signal representing a notification of the existence of an alignment fault and identification of the tower having the alignment fault, as shown in block 312. The notification signal may then be used to troubleshoot the irrigation system 100. As described before, an inspector may go straight to the alignment faulted tower instead of having to search the entire irrigation system 100.

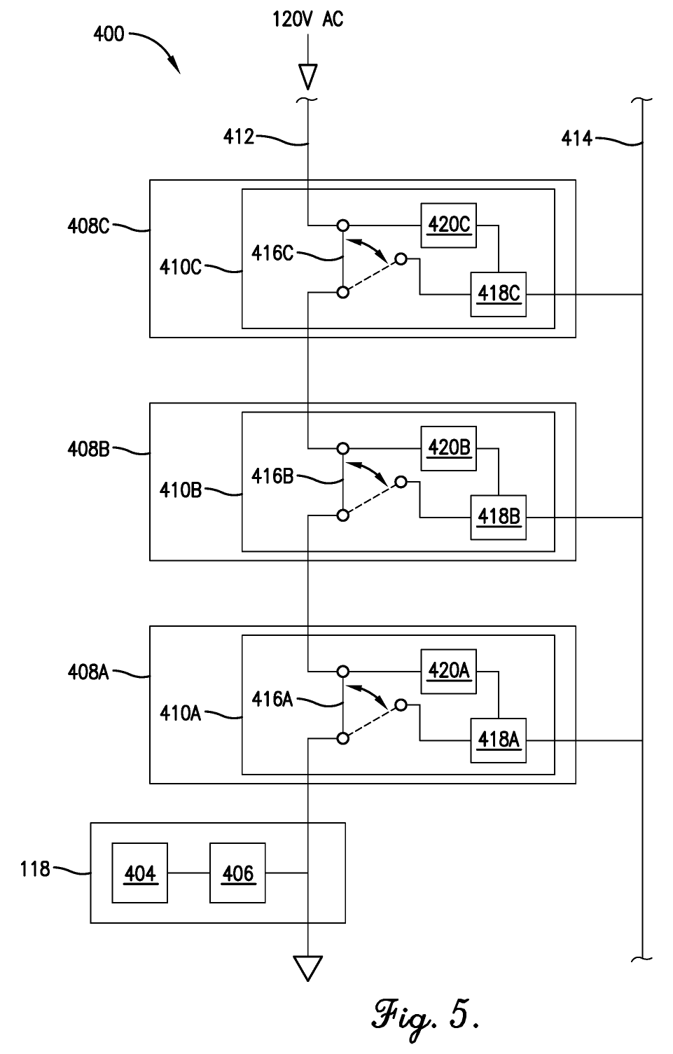

Turning to FIG. 5, a control system 400 constructed in accordance with another embodiment of the invention will now be described in detail. The control system 400 may be similar to control system 104 described above in that the control system 400 may be configured to control the irrigation system 100, intake commands and data from an operator or other source, and outputs statuses, data, alerts, and notifications relating to operation of the irrigation system 100. The control system 400 may also detect an alignment fault and determine which tower has the identified alignment fault. The control system 400 may include a central control panel 402 having a central controller 404 and an active RFID transceiver 406, and a plurality of tower control panels 408A-C each having a respective tower controller 410A-C. The control system 400 may also include a safety cable 412, a common cable 414, a plurality of safety switches 416A-C, and a plurality of passive RFID transceivers 418A-C. In one embodiment, the control system 400 further includes a plurality of power sources 420A-C for powering the passive RFID transceiver 418A-C.

The central control panel 402 and hence the central controller 404 may be positioned on or near the fixed center pivot 106 and may be communicatively connected to the tower controllers 410A-C. The central controller 404 may comprise one or more processors that include electronic hardware components such as microprocessors (single-core or multi-core), microcontrollers, digital signal processors (DSPs), field-programmable gate arrays (FPGAs), analog and/or digital application-specific integrated circuits (ASICs), intelligence circuitry, or the like, or combinations thereof. The central controller 404 may generally execute, process, or run instructions, code, code segments, code statements, software, firmware, programs, applications, apps, processes, services, daemons, or the like. The central controller 404 may also include hardware components such as registers, finite-state machines, sequential and combinational logic, configurable logic blocks, and other electronic circuits that can perform the functions necessary for the operation of the current invention. In certain embodiments, the central controller 404 may include multiple computational components and functional blocks that are packaged separately but function as a single unit. In some embodiments, the central controller 404 may further include multiprocessor architectures, parallel processor architectures, processor clusters, and the like, which provide high performance computing. The central controller 404 may be in electronic communication with the tower controllers 410A-C and other electronic components through serial or parallel links that include universal busses, address busses, data busses, control lines, and the like. In addition, the central controller 404 may include analog to digital converters (ADCs) to convert analog electronic signals to (streams of) digital data values and/or digital to analog converters (DACs) to convert (streams of) digital data values to analog electronic signals.

The central controller 404 may be operable, configured, and/or programmed to perform the functions, operations, processes, methods, and/or algorithms by utilizing hardware, software, firmware, or combinations thereof. The central controller 404 may also have access to, and be in electronic communication with, cloud computing services, wherein a portion of the functions, operations, processes, methods, and/or algorithms of the central controller 404 are performed by computing resources off-site. Additionally, or alternatively, the central controller 404 may include components, such as cloud computing components, that are physically located in a plurality of different geolocations. The components are able to communicate with each other to provide cohesive operation.

The active RFID transceiver 406 may be positioned in the central control panel 402 and connected to the safety cable 412. The active RFID transceiver 406 may be configured to send an excitation signal therethrough.

Each of the tower control panels 408A-C and hence each of the tower controllers 410A-C may be positioned on or near one of the towers 102A-C and may be communicatively connected to the other tower controllers 410A-C and the central controller 404. The tower controllers 410A-C may be substantially similar and thus only tower controller 410A will be described in detail. Much like the central controller 404, the tower controller 410A may comprise one or more processors that include electronic hardware components such as microprocessors (single-core or multi-core), microcontrollers, digital signal processors (DSPs), field-programmable gate arrays (FPGAs), analog and/or digital application-specific integrated circuits (ASICs), intelligence circuitry, or the like, or combinations thereof. The tower controller 410A may generally execute, process, or run instructions, code, code segments, code statements, software, firmware, programs, applications, apps, processes, services, daemons, or the like. The tower controller 410A may also include hardware components such as registers, finite-state machines, sequential and combinational logic, configurable logic blocks, and other electronic circuits that can perform the functions necessary for the operation of the current invention. In certain embodiments, the tower controller 410A may include multiple computational components and functional blocks that are packaged separately but function as a single unit. In some embodiments, the tower controller 410A may further include multiprocessor architectures, parallel processor architectures, processor clusters, and the like, which provide high performance computing. The tower controller 410A may be in electronic communication with the other tower controllers 410A-C, the central controller 404, and other electronic components through serial or parallel links that include universal busses, address busses, data busses, control lines, and the like. In addition, the tower controller 410A may include analog to digital converters (ADCs) to convert analog electronic signals to (streams of) digital data values and/or digital to analog converters (DACs) to convert (streams of) digital data values to analog electronic signals.

The tower controller 410A may be operable, configured, and/or programmed to perform the functions, operations, processes, methods, and/or algorithms by utilizing hardware, software, firmware, or combinations thereof. The tower controller 410A may also have access to, and be in electronic communication with, cloud computing services, wherein a portion of the functions, operations, processes, methods, and/or algorithms of the tower controller 410A are performed by computing resources off-site. Additionally, or alternatively, the tower controller 410A may include components, such as cloud computing components, that are physically located in a plurality of different geolocations. The components are able to communicate with each other to provide cohesive operation.

The safety cable 412 may extend from the central pivot 106 to the end tower 102D and may provide power to and be communicatively connected to the central controller 404 and the tower controllers 410A-C. The safety cable 412 may be an irrigation cable as defined in the National Electric Code (NFPA 70) edition 2020 (incorporated herein by reference in its entirety) in section 675.4. The safety cable 412 may include discrete insulated conductors, an inner jacket, a metallic covering, an outer jacket, and the like. The safety cable 412 may distribute electrical power and command signals to the tower controllers 410A-C. The safety cable 412 may carry 120VAC power or the like.

The common cable 414 may extend from the end tower 102D to the central pivot 106 and may act as a neutral cable path for certain communication signals as discussed below. Much like the safety cable 412, the common cable 414 may be an irrigation cable as defined previously. The common cable 414 may include discrete insulated conductors, an inner jacket, a metallic covering, an outer jacket, and the like. The common cable 414 may complete a signal circuit with the safety cable 412, one of the safety switches 416A-C, and a corresponding one of the passive RFID transceivers 418A-C as discussed below.

The safety switches 416A-C may be substantially similar so only safety switch 416A will be described in detail. The safety switch 416A may be electrically connected to the safety cable 412 via a normally closed pole to form a normally closed circuit along with the other safety switches. The safety switch 416A may be configured to open via a normally open pole, typically upon the corresponding span becoming misaligned. In the open state, the safety switch 416A may form a circuit with the safety cable 412, the passive RFID transceiver 418A, and the common cable 414.

The passive RFID transceivers 418A-C may be substantially similar and thus only passive RFID transceiver 418A will be described in detail. The passive RFID transceiver 418A may be positioned on or near tower 102A and wired between the normally open pole of the safety switch 416A and the common cable 414. The passive RFID transceiver 418A may be configured to emit an identification signal when energized and transmit the identification signal back to the central controller 404.

The power sources 420A-C may be electrically connected to the passive RFID transceivers 418A-C and may be batteries, capacitors, and the like. The power sources 420A-C may be normally connected to the safety cable 412 so that they are charged when the circuit is closed. Alternatively, the passive RFID transceivers 418A-C could be powered directly when connected to the safety cable 412.

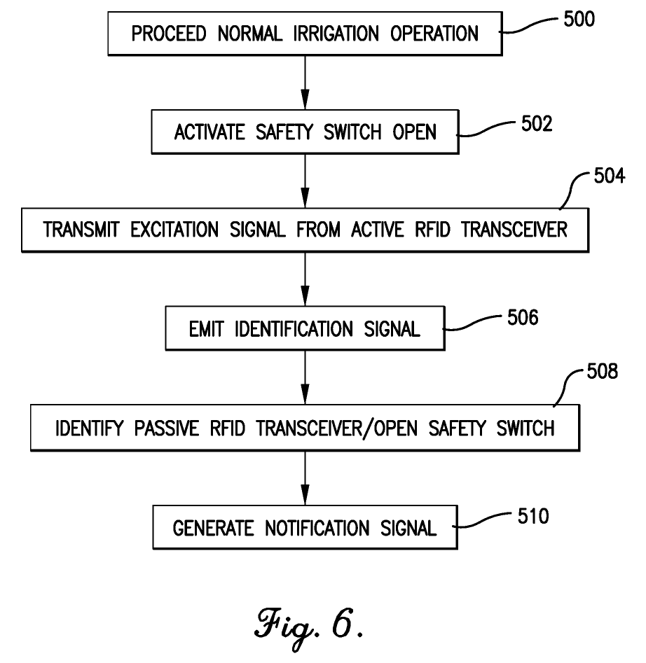

Turning to FIG. 6, use of the irrigation system 100 with control system 400 for detecting an alignment fault and identifying which tower has the alignment fault will now be described in more detail. The safety switches 4162A-C may be electrically connected to the safety cable 412 via a normally closed pole to form a normally closed circuit along with the other safety switches. The mobile irrigation system 100 may traverse a field for irrigation, application of agricultural products, or the like, as shown in block 500. One of the safety switches 416A-C may then be disconnected from a normally closed pole to a normally open pole such that the corresponding passive RFID transceiver 418A-C is electrically connected back to the central controller 404, as shown in block 502. This indicates an alignment fault.

The active RFID transceiver 406 may then transmit an excitation signal via the safety cable 412, as shown in block 504. The excitation signal may excite the now-connected passive RFID transceiver 418A-C. The now-connected passive RFID transceiver 418A-C may in turn emit an identification signal to the active RFID transceiver 406 via the safety cable 412 or the common cable 414, as shown in block 506. To that end, the corresponding power source 420A-C may power the passive RFID transceiver 418A-C to emit the identification signal. The active RFID transceiver 406 may thus receive the identification signal and relay the identification signal to the central controller 404.

The central controller 404 may then correlate the identification signal to the tower with the corresponding open safety switch 416A-C, as shown in block 508. Alternatively, the identification signal (or another signal including identifying information) may be transmitted to a cloud computing service to determine which tower has a corresponding open safety switch 416A-C. The central controller 404 may then generate and transmit a notification signal representing a notification of the existence of an alignment fault and identification of the tower having the alignment fault, as shown in block 510. The notification signal may then be used to troubleshoot the irrigation system 100. As described before, an inspector may go straight to the alignment faulted tower instead of having to search the entire irrigation system 100.

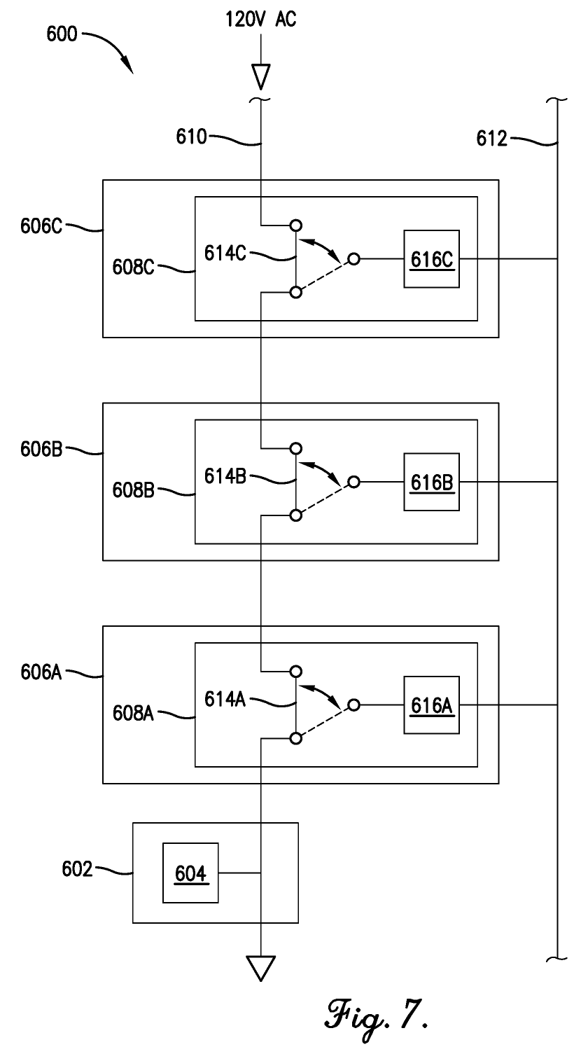

Turning to FIG. 7, a control system 600 constructed in accordance with another embodiment of the invention will now be described in detail. The control system 600 may be similar to the control systems described above in that the control system 600 may be configured to control the irrigation system 100, intake commands and data from an operator or other source, and outputs statuses, data, alerts, and notifications relating to operation of the irrigation system 100. The control system 600 may also detect an alignment fault and determine which tower has the identified alignment fault. The control system 600 may include a central control panel 602 having a central controller 604 and a plurality of tower control panels 606A-C each having a tower controller 608A-C. The control system 600 may also include a safety cable 610, a common cable 612, a plurality of safety switches 614A-C, and a plurality of active transceivers 616A-C.

The central control panel 602 and hence the central controller 604 may be positioned on or near the fixed center pivot 106 and may be communicatively connected to the tower controllers 608A-C. The central controller 604 may comprise one or more processors that include electronic hardware components such as microprocessors (single-core or multi-core), microcontrollers, digital signal processors (DSPs), field-programmable gate arrays (FPGAs), analog and/or digital application-specific integrated circuits (ASICs), intelligence circuitry, or the like, or combinations thereof. The central controller 604 may generally execute, process, or run instructions, code, code segments, code statements, software, firmware, programs, applications, apps, processes, services, daemons, or the like. The central controller 604 may also include hardware components such as registers, finite-state machines, sequential and combinational logic, configurable logic blocks, and other electronic circuits that can perform the functions necessary for the operation of the current invention. In certain embodiments, the central controller 604 may include multiple computational components and functional blocks that are packaged separately but function as a single unit. In some embodiments, the central controller 604 may further include multiprocessor architectures, parallel processor architectures, processor clusters, and the like, which provide high performance computing. The central controller 604 may be in electronic communication with the tower controllers 608A-C and other electronic components through serial or parallel links that include universal busses, address busses, data busses, control lines, and the like. In addition, the central controller 604 may include analog to digital converters (ADCs) to convert analog electronic signals to (streams of) digital data values and/or digital to analog converters (DACs) to convert (streams of) digital data values to analog electronic signals.

The central controller 604 may be operable, configured, and/or programmed to perform the functions, operations, processes, methods, and/or algorithms by utilizing hardware, software, firmware, or combinations thereof. The central controller 604 may also have access to, and be in electronic communication with, cloud computing services, wherein a portion of the functions, operations, processes, methods, and/or algorithms of the central controller 604 are performed by computing resources off-site. Additionally, or alternatively, the central controller 604 may include components, such as cloud computing components, that are physically located in a plurality of different geolocations. The components are able to communicate with each other to provide cohesive operation.

Each of the tower control panels 606A-C and hence each of the tower controllers 608A-C may be positioned on or near one of the towers A-C and may be communicatively connected to the other tower controllers 608A-C and the central controller 604. The tower controllers 608A-C may be substantially similar and thus only tower controller 608A will be described in detail. Much like the central controller 604, the tower controller 608A may comprise one or more processors that include electronic hardware components such as microprocessors (single-core or multi-core), microcontrollers, digital signal processors (DSPs), field-programmable gate arrays (FPGAs), analog and/or digital application-specific integrated circuits (ASICs), intelligence circuitry, or the like, or combinations thereof. The tower controller 608A may generally execute, process, or run instructions, code, code segments, code statements, software, firmware, programs, applications, apps, processes, services, daemons, or the like. The tower controller 608A may also include hardware components such as registers, finite-state machines, sequential and combinational logic, configurable logic blocks, and other electronic circuits that can perform the functions necessary for the operation of the current invention. In certain embodiments, the tower controller 608A may include multiple computational components and functional blocks that are packaged separately but function as a single unit. In some embodiments, the tower controller 608A may further include multiprocessor architectures, parallel processor architectures, processor clusters, and the like, which provide high performance computing. The tower controller 608A may be in electronic communication with the other tower controllers 608A-C, the central controller 604, and other electronic components through serial or parallel links that include universal busses, address busses, data busses, control lines, and the like. In addition, the tower controller 608A may include analog to digital converters (ADCs) to convert analog electronic signals to (streams of) digital data values and/or digital to analog converters (DACs) to convert (streams of) digital data values to analog electronic signals.

The tower controller 608A may be operable, configured, and/or programmed to perform the functions, operations, processes, methods, and/or algorithms by utilizing hardware, software, firmware, or combinations thereof. The tower controller 608A may also have access to, and be in electronic communication with, cloud computing services, wherein a portion of the functions, operations, processes, methods, and/or algorithms of the tower controller 608A are performed by computing resources off-site. Additionally, or alternatively, the tower controller 608A may include components, such as cloud computing components, that are physically located in a plurality of different geolocations. The components are able to communicate with each other to provide cohesive operation.

The safety cable 610 may extend from the central pivot 106 to the end tower 102D and may provide power to and be communicatively connected to the central controller 604 and the tower controllers 608A-C. The safety cable 610 may be an irrigation cable as defined in the National Electric Code (NFPA 70) edition 2020 (incorporated herein by reference in its entirety) in section 675.4. The safety cable 610 may include discrete insulated conductors, an inner jacket, a metallic covering, an outer jacket, and the like. The safety cable 610 may distribute electrical power and command signals to the tower controllers 608A-C. The safety cable 610 may carry 120VAC power or the like.

The common cable 612 may extend from the end tower 102D to the central pivot 106 and may act as a neutral cable path for certain communication signals as discussed below. Much like the safety cable 610, the common cable 612 may be an irrigation cable as defined previously. The common cable 612 may include discrete insulated conductors, an inner jacket, a metallic covering, an outer jacket, and the like.

The safety switches 614A-C may be substantially similar so only safety switch 614A will be described in detail. The safety switch 614A may be electrically connected to the safety cable 610 via a normally closed pole to form a normally closed circuit along with the other safety switches. The safety switch 614A may be configured to open via a normally open pole, typically upon the corresponding span becoming misaligned. In the open state, the safety switch 614A may form a circuit with the safety cable 610, the active transceiver 616A, and the common cable 612.

The active transceivers 616A-C may be substantially similar and thus only active transceiver 616A will be described in detail. The active transceiver 616A may be positioned on or near tower 102A and wired between the normally open pole of the safety switch 614A and the common cable 612. The active transceiver 616A may be configured to transmit an encoded identification signal transmit the identification signal back to the central controller 604 via the safety cable 610. The active transceiver 616A may be pre-programmed, programmed in the field, or adjusted by DIP switches in the field.

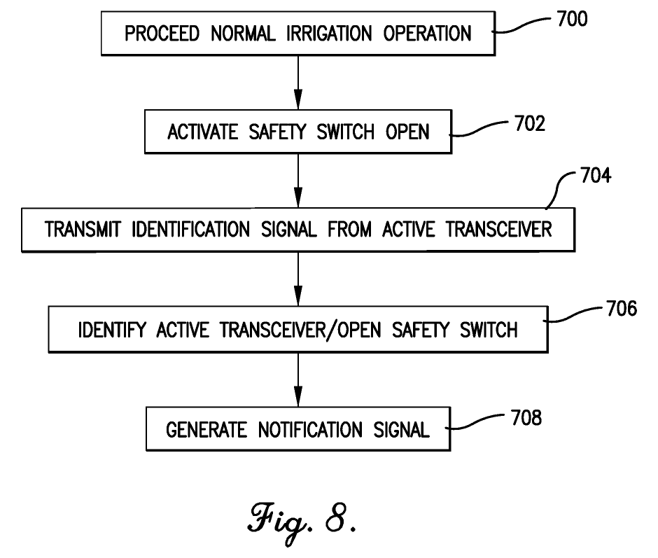

Turning to FIG. 8, use of the irrigation system 100 with control system 600 for detecting an alignment fault and identifying which tower has the alignment fault will now be described in more detail. The safety switches 614A-C may initially be electrically connected to the safety cable 610 via a normally closed pole to form a normally closed circuit along with the other safety switches. The mobile irrigation system 100 may traverse a field for irrigation, application of agricultural products, or the like, as shown in block 700. One of the safety switches 614A-C may then be disconnected from the normally closed pole to a normally open pole such that the corresponding active transceiver 616A-C is electrically connected back to the central controller 604, as shown in block 702. This indicates an alignment fault.

The now-connected active transceiver 616A-C may then transmit an identification signal via the safety cable 610 to the central controller 604, as shown in block 704. The identification signal may be an encoded signal and may thus be decoded at the central controller 604. In addition to tower identification, the identification signal may include operational information, tower status, and other information regarding tower operation prior to or after the corresponding safety switch 614A-C opened. This information may provide clues or insight into the case of the mis-alignment.

The now-connected active transceiver 616A-C may be powered by a low voltage power signal transmitted by the central controller 604 via the safety cable 610 once the corresponding safety switch 614A-C has been tripped. The identification signal must therefore be coupled over the low voltage power signal.

The central controller 604 may then correlate the identification signal to the tower with the corresponding open safety switch 614A-C, as shown in block 706. Alternatively, the identification signal (or another signal including identifying information) may be transmitted to a cloud computing service to determine which tower has a corresponding open safety switch 614A-C. The central controller 604 may then generate and transmit a notification signal representing a notification of the existence of an alignment fault and identification of the tower having the alignment fault, as shown in block 708. The notification signal may then be used to troubleshoot the irrigation system 100. As described before, an inspector may go straight to the alignment faulted tower instead of having to search the entire irrigation system 100.

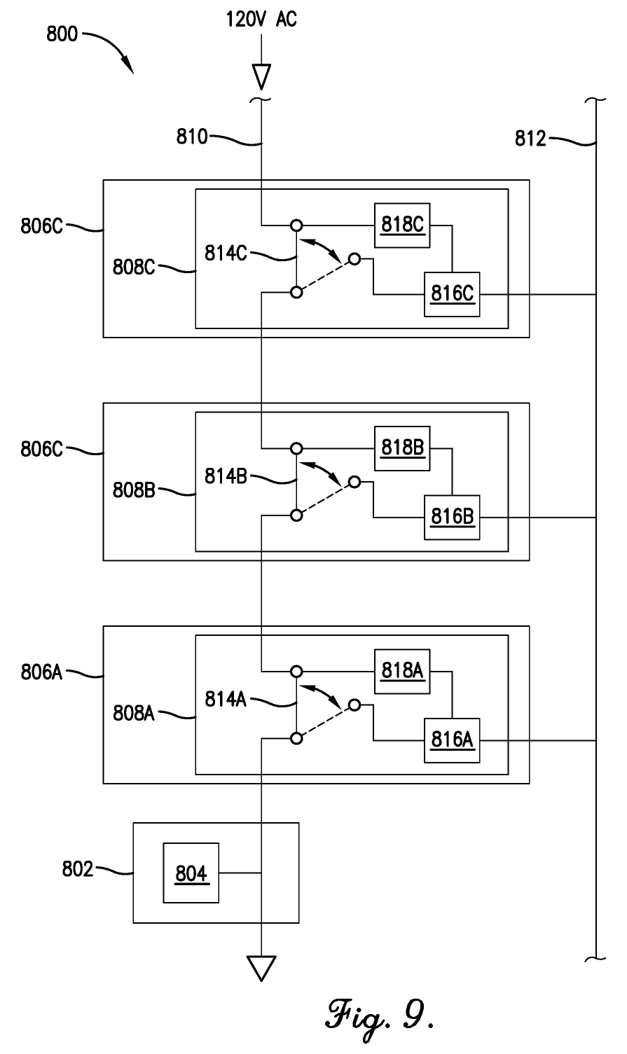

Turning to FIG. 9, a control system 800 constructed in accordance with another embodiment of the invention will now be described in detail. The control system 800 may be similar to the control systems described above in that the control system 800 may be configured to control the irrigation system 100, intake commands and data from an operator or other source, and outputs statuses, data, alerts, and notifications relating to operation of the irrigation system 100. The control system 800 may also detect an alignment fault and determine which tower has the identified alignment fault. The control system 800 may include a central control panel 802 having a central controller 804 and a plurality of tower control panels 806A-C each having a tower controller 808A-C. The control system 800 may also include a safety cable 810, a common cable 812, a plurality of safety switches 814A-C, a plurality of active transceivers 816A-C, and a plurality of power sources 818A-C.

The central control panel 802 and hence the central controller 804 may be positioned on or near the fixed center pivot 106 and may be communicatively connected to the tower controllers 808A-C. The central controller 804 may comprise one or more processors that include electronic hardware components such as microprocessors (single-core or multi-core), microcontrollers, digital signal processors (DSPs), field-programmable gate arrays (FPGAs), analog and/or digital application-specific integrated circuits (ASICs), intelligence circuitry, or the like, or combinations thereof. The central controller 804 may generally execute, process, or run instructions, code, code segments, code statements, software, firmware, programs, applications, apps, processes, services, daemons, or the like. The central controller 804 may also include hardware components such as registers, finite-state machines, sequential and combinational logic, configurable logic blocks, and other electronic circuits that can perform the functions necessary for the operation of the current invention. In certain embodiments, the central controller 804 may include multiple computational components and functional blocks that are packaged separately but function as a single unit. In some embodiments, the central controller 804 may further include multiprocessor architectures, parallel processor architectures, processor clusters, and the like, which provide high performance computing. The central controller 804 may be in electronic communication with the tower controllers 808A-C and other electronic components through serial or parallel links that include universal busses, address busses, data busses, control lines, and the like. In addition, the central controller 804 may include analog to digital converters (ADCs) to convert analog electronic signals to (streams of) digital data values and/or digital to analog converters (DACs) to convert (streams of) digital data values to analog electronic signals.

The central controller 804 may be operable, configured, and/or programmed to perform the functions, operations, processes, methods, and/or algorithms by utilizing hardware, software, firmware, or combinations thereof. The central controller 804 may also have access to, and be in electronic communication with, cloud computing services, wherein a portion of the functions, operations, processes, methods, and/or algorithms of the central controller 804 are performed by computing resources off-site. Additionally, or alternatively, the central controller 804 may include components, such as cloud computing components, that are physically located in a plurality of different geolocations. The components are able to communicate with each other to provide cohesive operation.

Each of the tower controllers 808A-C may be positioned on or near one of the towers A-C and may be communicatively connected to the other tower controllers 808A-C and the central controller 804. The tower controllers 808A-C may be substantially similar and thus only tower controller 808A will be described in detail. Much like the central controller 804, the tower controller 808A may comprise one or more processors that include electronic hardware components such as microprocessors (single-core or multi-core), microcontrollers, digital signal processors (DSPs), field-programmable gate arrays (FPGAs), analog and/or digital application-specific integrated circuits (ASICs), intelligence circuitry, or the like, or combinations thereof. The tower controller 808A may generally execute, process, or run instructions, code, code segments, code statements, software, firmware, programs, applications, apps, processes, services, daemons, or the like. The tower controller 808A may also include hardware components such as registers, finite-state machines, sequential and combinational logic, configurable logic blocks, and other electronic circuits that can perform the functions necessary for the operation of the current invention. In certain embodiments, the tower controller 808A may include multiple computational components and functional blocks that are packaged separately but function as a single unit. In some embodiments, the tower controller 808A may further include multiprocessor architectures, parallel processor architectures, processor clusters, and the like, which provide high performance computing. The tower controller 808A may be in electronic communication with the other tower controllers 808A-C, the central controller 804, and other electronic components through serial or parallel links that include universal busses, address busses, data busses, control lines, and the like. In addition, the tower controller 808A may include analog to digital converters (ADCs) to convert analog electronic signals to (streams of) digital data values and/or digital to analog converters (DACs) to convert (streams of) digital data values to analog electronic signals.

The tower controller 808A may be operable, configured, and/or programmed to perform the functions, operations, processes, methods, and/or algorithms by utilizing hardware, software, firmware, or combinations thereof. The tower controller 808A may also have access to, and be in electronic communication with, cloud computing services, wherein a portion of the functions, operations, processes, methods, and/or algorithms of the tower controller 808A are performed by computing resources off-site. Additionally, or alternatively, the tower controller 808A may include components, such as cloud computing components, that are physically located in a plurality of different geolocations. The components are able to communicate with each other to provide cohesive operation.

The safety cable 810 may extend from the central pivot 106 to the end tower 102D and may provide power to and be communicatively connected to the central controller 804 and the tower controllers 808A-C. The safety cable 810 may be an irrigation cable as defined in the National Electric Code (NFPA 70) edition 2020 (incorporated herein by reference in its entirety) in section 675.4. The safety cable 810 may include discrete insulated conductors, an inner jacket, a metallic covering, an outer jacket, and the like. The safety cable 810 may distribute electrical power and command signals to the tower controllers 808A-C. The safety cable 810 may carry 120VAC power or the like.

The common cable 812 may extend from the end tower 102D to the central pivot 106 and may act as a neutral cable path for certain communication signals as discussed below. Much like the safety cable 810, the common cable 812 may be an irrigation cable as defined previously. The common cable 812 may include discrete insulated conductors, an inner jacket, a metallic covering, an outer jacket, and the like.

The safety switches 814A-C may be substantially similar so only safety switch 814A will be described in detail. The safety switch 814A may be electrically connected to the safety cable 810 via a normally closed pole to form a normally closed circuit along with the other safety switches. The safety switch 814A may be configured to open via a normally open pole, typically upon the corresponding span becoming misaligned. In the open state, the safety switch 814A may form a circuit with the safety cable 810, the active transceiver 816A, and the common cable 812.

The active transceivers 816A-C may be substantially similar and thus only active transceiver 816A will be described in detail. The active transceiver 816A may be positioned on or near tower 102A and wired between the normally open pole of the safety switch 814A and the common cable 812. The active transceiver 816A may be configured to transmit an encoded identification signal transmit the identification signal back to the central controller 804 via the safety cable 810. The active transceivers 816A-C may be pre-programmed, programmed in the field, or adjusted by DIP switches in the field.

The power sources 818A-C may be substantially similar so only power source 818A will be described in detail. The power source 818A may be a battery or super capacitor. The power source 818A may be normally connected to the safety cable 810 via the normally closed pole of the safety switch 814A so that the power source 818A is charging when the safety switch 814A is closed. The power source 818A may thus be charged and configured to power the active transceiver 816A when the safety switch 814A is open.

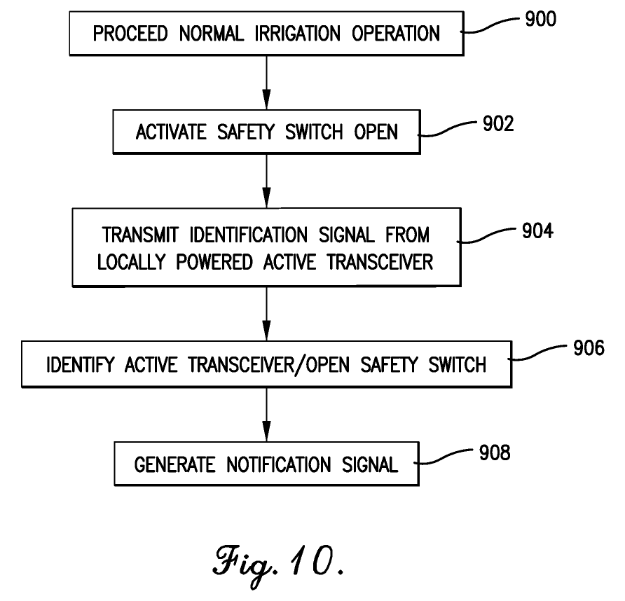

Turning to FIG. 10, use of the irrigation system 100 with control system 800 for detecting an alignment fault and identifying which tower has the alignment fault will now be described in more detail. The safety switches 814A-C may initially be electrically connected to the safety cable 810 via a normally closed pole to form a normally closed circuit along with the other safety switches. The mobile irrigation system 100 may traverse a field for irrigation, application of agricultural products, or the like, as shown in block 900. One of the safety switches 814A-C may then be disconnected from the normally closed pole to a normally open pole such that the corresponding active transceiver 816A-C is electrically connected back to the central controller 804, as shown in block 902. This indicates an alignment fault.

The now-connected active transceiver 816A-C may then transmit an identification signal via the safety cable 810 to the central controller 804, as shown in block 904. To that end, the now-connected active transceiver 816A-C may be powered by the corresponding power source 818A-C to transmit the identification signal. The identification signal may be an encoded signal and thus may be decoded at the central controller 804. In addition to tower identification, the identification signal may include operational information, tower status, and other information regarding tower operation prior to or after the corresponding safety switch 814A-C opened. This information may provide clues or insight into the case of the mis-alignment.

The central controller 804 may then correlate the identification signal to the tower with the corresponding open safety switch 814A-C, as shown in block 906. Alternatively, the identification signal (or another signal including identifying information) may be transmitted to a cloud computing service to determine which tower has a corresponding open safety switch 814A-C. The central controller 804 may then generate and transmit a notification signal representing a notification of the existence of an alignment fault and identification of the tower having the alignment fault, as shown in block 908. The notification signal may then be used to troubleshoot the irrigation system 100. As described before, an inspector may go straight to the alignment faulted tower instead of having to search the entire irrigation system 100.

For embodiments involving a super capacitor to power an identification signal generating component, once the super capacitor has lost its charge, the identification signal generating component will stop transmitting the identification signal. The identification signal must therefore be received and decoded before the super capacitor is discharged. At this point, if an identification signal is still needed, the identification signal generating component could be powered from the safety cable via the normally closed pole. However, this may require a user command to power the safety cable once the irrigation system has stopped for an alignment safety fault. This scenario also would likely not allow a second check of the safety switch (e.g., ten to fifteen minutes after shutdown) to see if the irrigation system has relaxed allowing the safety switch to close. Nevertheless, such a check can be achieved during a normal alignment safety circuit check, which will also re-charge the super capacitor and allow the identification generating component to transmit an identification signal once more.

In several embodiments, it is also important to ensure no “sneak path” for the 120VAC charge to pass from the normally closed pole of the safety switch, through the identification signal generating component, to the common terminal of the safety switch. Such a sneak path would give a false positive of the alignment switch being closed.

### Additional Considerations

Throughout this specification, references to “one embodiment”, “an embodiment”, or “embodiments” mean that the feature or features being referred to are included in at least one embodiment of the technology. Separate references to “one embodiment”, “an embodiment”, or “embodiments” in this description do not necessarily refer to the same embodiment and are also not mutually exclusive unless so stated and/or except as will be readily apparent to those skilled in the art from the description. For example, a feature, structure, act, etc. described in one embodiment may also be included in other embodiments, but is not necessarily included. Thus, the current invention can include a variety of combinations and/or integrations of the embodiments described herein.

Although the present application sets forth a detailed description of numerous different embodiments, it should be understood that the legal scope of the description is defined by the words of the claims set forth at the end of this patent and equivalents. The detailed description is to be construed as exemplary only and does not describe every possible embodiment since describing every possible embodiment would be impractical. Numerous alternative embodiments may be implemented, using either current technology or technology developed after the filing date of this patent, which would still fall within the scope of the claims.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Certain embodiments are described herein as including logic or a number of routines, subroutines, applications, or instructions. These may constitute either software (e.g., code embodied on a machine-readable medium or in a transmission signal) or hardware. In hardware, the routines, etc., are tangible units capable of performing certain operations and may be configured or arranged in a certain manner. In example embodiments, one or more computer systems (e.g., a standalone, client or server computer system) or one or more hardware modules of a computer system (e.g., a processor or a group of processors) may be configured by software (e.g., an application or application portion) as computer hardware that operates to perform certain operations as described herein.

In various embodiments, computer hardware, such as a processor, may be implemented as special purpose or as general purpose. For example, the processor may comprise dedicated circuitry or logic that is permanently configured, such as an application-specific integrated circuit (ASIC), or indefinitely configured, such as an FPGA, to perform certain operations. The processor may also comprise programmable logic or circuitry (e.g., as encompassed within a general-purpose processor or other programmable processor) that is temporarily configured by software to perform certain operations. It will be appreciated that the decision to implement the processor as special purpose, in dedicated and permanently configured circuitry, or as general purpose (e.g., configured by software) may be driven by cost and time considerations.

Accordingly, the term “processor” or equivalents should be understood to encompass a tangible entity, be that an entity that is physically constructed, permanently configured (e.g., hardwired), or temporarily configured (e.g., programmed) to operate in a certain manner or to perform certain operations described herein. Considering embodiments in which the processor is temporarily configured (e.g., programmed), each of the processors need not be configured or instantiated at any one instance in time. For example, where the processor comprises a general-purpose processor configured using software, the general-purpose processor may be configured as respective different processors at different times. Software may accordingly configure the processor to constitute a particular hardware configuration at one instance of time and to constitute a different hardware configuration at a different instance of time.

Computer hardware components, such as communication elements, memory elements, processors, and the like, may provide information to, and receive information from, other computer hardware components. Accordingly, the described computer hardware components may be regarded as being communicatively coupled. Where multiple of such computer hardware components exist contemporaneously, communications may be achieved through signal transmission (e.g., over appropriate circuits and buses) that connect the computer hardware components. In embodiments in which multiple computer hardware components are configured or instantiated at different times, communications between such computer hardware components may be achieved, for example, through the storage and retrieval of information in memory structures to which the multiple computer hardware components have access. For example, one computer hardware component may perform an operation and store the output of that operation in a memory device to which it is communicatively coupled. A further computer hardware component may then, at a later time, access the memory device to retrieve and process the stored output. Computer hardware components may also initiate communications with input or output devices, and may operate on a resource (e.g., a collection of information).

The various operations of example methods described herein may be performed, at least partially, by one or more processors that are temporarily configured (e.g., by software) or permanently configured to perform the relevant operations. Whether temporarily or permanently configured, such processors may constitute processor-implemented modules that operate to perform one or more operations or functions. The modules referred to herein may, in some example embodiments, comprise processor-implemented modules.

Similarly, the methods or routines described herein may be at least partially processor-implemented. For example, at least some of the operations of a method may be performed by one or more processors or processor-implemented hardware modules. The performance of certain of the operations may be distributed among the one or more processors, not only residing within a single machine, but deployed across a number of machines. In some example embodiments, the processors may be located in a single location (e.g., within a home environment, an office environment or as a server farm), while in other embodiments the processors may be distributed across a number of locations.

Unless specifically stated otherwise, discussions herein using words such as “processing”, “computing”, “calculating”, “determining”, “presenting”, “displaying”, or the like may refer to actions or processes of a machine (e.g., a computer with a processor and other computer hardware components) that manipulates or transforms data represented as physical (e.g., electronic, magnetic, or optical) quantities within one or more memories (e.g., volatile memory, non-volatile memory, or a combination thereof), registers, or other machine components that receive, store, transmit, or display information.

As used herein, the terms “comprises”, “comprising”, “includes”, “including”, “has”, “having”, or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus.

The patent claims at the end of this patent application are not intended to be construed under 35 U.S.C. § 112(f) unless traditional means-plus-function language is expressly recited, such as “means for” or “step for” language being explicitly recited in the claim(s).

Although the technology has been described with reference to the embodiments illustrated in the attached drawing figures, it is noted that equivalents may be employed and substitutions made herein without departing from the scope of the technology as recited in the claims.

What is claimed is:

1. A control system for a mobile irrigation system having a plurality of mobile towers supporting a plurality of spans, the control system comprising:
a plurality of safety switches each positioned on or near one of the mobile towers and configured to change from a closed position to an open position;
a plurality of transceivers each associated with one of the plurality of safety switches, positioned on or near one of the mobile towers, and configured to transmit an identification signal upon a corresponding safety switch being in the open position; and
a central controller configured to receive the identification signal such that the safety switch in the open position is identified based on the identification signal.

2. The control system of claim 1, wherein the plurality of transceivers are frequency generators each configured to impart a unique frequency to the corresponding identification signal such that the central controller is configured to identify the safety switch in the open position based on the unique frequency.

3. The control system of claim 2, wherein each of the plurality of transceivers is pre-programmed for the corresponding unique frequency.

4. The control system of claim 2, wherein each of the plurality of transceivers includes a dip switch configured to be adjusted to set the unique frequency.

5. The control system of claim 1, further comprising a safety cable electrically connecting the plurality of switches, wherein each of the plurality of safety switches is configured to electrically connect a corresponding one of the plurality of transceivers to the safety cable when the safety switch is in the open position for transmitting the identification signal to the central controller.

6. The control system of claim 1, wherein the central controller includes a transceiver configured to decode the identification signal.

7. The control system of claim 1, wherein the identification signal has a predetermined power level and the central controller is configured to identify the safety switch in the open position based on a loss of signal strength of the identification signal as received by the central controller.

8. The control system of claim 1, wherein the central controller is configured to identify the safety switch in the open position based on the identification signal and display a notification indicating the identified safety switch via a user interface.

9. The control system of claim 1, wherein the central controller is configured to transmit a signal to a cloud computing system for identifying the safety switch in the open position based on the identification signal.

10. A control system for a mobile irrigation system having a plurality of mobile towers supporting a plurality of spans, the control system comprising:
a plurality of safety switches each positioned on or near one of the mobile towers and configured to change from a closed position to an open position;
a plurality of passive RFID transceivers each associated with one of the plurality of safety switches, positioned on or near one of the mobile towers, and configured to transmit an identification signal upon a corresponding safety switch being in the open position and an excitation signal being transmitted to the passive RFID transceiver; and
a central controller including an active radio frequency identification device (RFID) transceiver configured to transmit the excitation signal, the central controller being configured to receive the identification signal such that the safety switch in the open position is identified based on the identification signal.

11. The control system of claim 10, further comprising a plurality of power storage devices each electrically connected to a corresponding safety switch when the corresponding safety switch is in the closed position and electrically connected to a corresponding one of the plurality of passive RFID transceivers when the corresponding safety switch is in the open position such that the power storage device is charged when the corresponding safety switch is in the closed position and discharges to the corresponding passive RFID transceiver when the corresponding safety switch is in the open position.

12. The control system of claim 11, wherein the power storage device is at least one of a battery and a super capacitor.

13. The control system of claim 10, wherein the central controller is configured to identify the safety switch in the open position based on the identification signal.

14. The control system of claim 10, wherein the central controller is configured to transmit a signal to a cloud computing system for identifying the safety switch in the open position based on the identification signal.

15. A control system for a mobile irrigation system having a plurality of mobile towers supporting a plurality of spans, the control system comprising:
a plurality of safety switches each positioned on or near one of the mobile towers and configured to change from a closed position to an open position;
a plurality of active RFID transceivers each associated with one of the plurality of safety switches, positioned on or near one of the mobile towers and, configured to transmit an identification signal to the central controller upon a corresponding safety switch being in the open position; and
a central controller for receiving the identification signal such that the safety switch in the open position is identified based on the identification signal.

16. The control system of claim 15, wherein the identification signal includes tower operational information.

17. The control system of claim 16, wherein the tower operation information includes data corresponding to tower operation immediately prior to or immediately after the corresponding safety switch changes to the open position.

18. The control system of claim 15, wherein each of the plurality of active RFID transceivers is configured to be powered by a low voltage signal via the corresponding safety switch in the open position.

19. The control system of claim 15, further comprising a plurality of power storage devices each electrically connected to a corresponding safety switch when the corresponding safety switch is in the closed position and electrically connected to a corresponding one of the plurality of active RFID transceivers when the corresponding safety switch is in the open position such that the power storage device is charged when the corresponding safety switch is in the closed position and discharges to the corresponding active RFID transceiver when the corresponding safety switch is in the open position.

20. The control system of claim 15, wherein the transceiver is a transponder configured to transmit the identification signal up receiving an excitation signal.
